(19) United States
(12) Patent Application Publication
(10) Pub. No.: US 2012/0196443 A1
(43) Pub. Date: Aug. 2, 2012

(54) CHEMICAL MECHANICAL POLISHING METHOD

(75) Inventor: WUFENG DENG, Shanghai (CN)

(73) Assignee: Semiconductor Manufacturing International (Shanghai) Corporation, Shanghai (CN)

(21) Appl. No.: 13/272,197

(22) Filed: Oct. 12, 2011

(30) Foreign Application Priority Data
Jan. 31, 2011 (CN) 201110034148.3
Jul. 26, 2011 (CN) 201110211074.6

(51) Int. Cl. H01L 21/306

(52) U.S. Cl. 438/693; 257/E21.23

(57) ABSTRACT

A Chemical Mechanical Polishing (CMP) method includes providing a semiconductor substrate having an overlying dielectric layer, performing a first grinding on the dielectric layer, wherein the first grinding produces organic residues on a surface of the dielectric layer after the first grinding. The method further includes performing a second grinding on the dielectric layer by using an alkaline solution to remove the organic residues on the surface of the dielectric layer. The organic residues remaining on the surface of the dielectric layer are removed by using the alkaline solution after the first grinding process is performed. The method additionally includes cleaning a grinding pad and the substrate using deionized water.

### CROSS-REFERENCES TO RELATED APPLICATIONS

The present application claims the priority of Chinese Patent Application No. 201110211074.6, entitled “CHEMICAL MECHANICAL POLISHING METHOD”, filed on Jul. 26, 2011, which claims the priority of Chinese Patent Application No. 201110034148.3, entitled “CHEMICAL MECHANICAL POLISHING METHOD”, and filed on Jan. 31, 2011, the entire disclosures of which are incorporated herein by reference.

### FIELD OF THE INVENTION

The present invention generally relates to semiconductor manufacture technology, and more particularly, to a chemical mechanical polishing method of planarizing a dielectric layer and removing organic residues remaining on the surface of the planarized dielectric layer.

### BACKGROUND OF THE INVENTION

In semiconductor technology, Chemical Mechanical Polishing (CMP) technology uses two types of grinding, a mechanical grinding and a chemical grinding, to planarize a wafer or a semiconductor layer. A flat surface of wafer or semiconductor layer is important for subsequent processes such as a thin film deposition process and the like. While performing a CMP process, a wafer to be grinded is pressed on a grinding pad by a grinding head which drives the wafer to be grinded to rotate in one direction, while the grinding pad rotates in the opposite direction. While the grinding is performed, adequate grinding slurry is added between the wafer to be grinded and the grinding pad by a slurry supply device. Then, with high speed rotations between the grinding pad and the wafer to be grinded, materials on the surface of the wafer to be grinded are stripped constantly, which are taken away by the grinding slurry. Further, a new surface of the wafer to be grinded performs chemical reactions and products thereof are stripped again. By repeating the above described processes and together with the combined effects of the chemical and mechanical grinding, the surface of the wafer will be planarized.

When a dielectric layer is grinded according to a conventional method, the surface of the wafer is abraded by grinding particles in oxidation grinding solution, which may cause scratches on the wafer surface. And organic residues may be produced by chemical additives in the grinding solution, which may adhere to the surface of the wafer and impact the quality and performance of the final device. In the prior art, after a main grinding performed to the wafer is finished, the organic residues left over on the surface of the wafer are normally removed by a cleaning device. For example, a deionized water device is usually used to perform the cleaning process. However, inventor of the present invention has conductor research works and discovered that the conventional method does not yield a satisfactory result in removing organic residues. Through numerous tests and measurements, inventor of the present invention found that after the wafer surface is cleaned by the cleaning device using deionized water, large amounts of the organic residues are still remained thereon, which impacts the performance of a final device.

Therefore, it is desirable to provide a CMP method that can effectively remove the organic residues on the surface of a planarized wafer.

### BRIEF SUMMARY OF THE INVENTION

An object of the present invention is to effectively remove organic residues adhering on a wafer surface during a Chemical Mechanical Polishing (CMP) process, so that the quality and performance of a final device will be improved.

Embodiments of the present invention provide a CMP method that includes providing a semiconductor substrate or a wafer having an overlying dielectric layer, performing a first grinding on the dielectric layer, wherein the first grinding produces organic residues on a surface of the dielectric layer, and performing a second grinding on the dielectric layer by using an alkaline solution to remove the organic residues on the surface of the dielectric layer.

Optionally, the alkaline solution includes grinding particles, a cleaning agent, a chelating agent, anti-corrosion compounds, and a surfactant.

Optionally, a weight percentage of the grinding particles in the alkaline solution is from about 1% to about 15%, a weight percentage of the cleaning agent in the alkaline solution is from about 0.1% to about 5%, a weight percentage of the chelating agent in the alkaline solution is from about 0.01% to about 2%, a weight percentage of the anti-corrosion compounds in the alkaline solution is from about 0.01% to about 2%, and a weight percentage of the surfactant in the alkaline solution is from about 0.01% to about 1%.

Optionally, the grinding particles comprises colloidal silica, silicon carbide, silicon nitride, aluminum oxide, or cerium dioxide. Optionally, the grinding particles have diameters within a range from about 35 nm to about 90 nm.

Optionally, the cleaning agent includes ammonium hydroxide or tetra alkyl ammonium hydroxide.

Optionally, the chelating agent includes ammonium citrate or ammonium oxalate.

Optionally, the anti-corrosion compounds include acetamidophenol or methoxyphenol.

Optionally, the surfactant includes polyoxyethylene or polypropylene.

Optionally, the alkaline solution has a pH value within a range from about 8 to about 10.

Optionally, during the first grinding, a pressure of a grinding head is ranged from about 0.85 psi to about 1.8 psi.

Optionally, during the second grinding, the pressure of the grinding head is ranged from about 0.5 psi to about 0.7 psi.

Optionally, the dielectric layer is a low-K dielectric layer.

Optionally, a dielectric constant K of the low-K layer is less than 3 (K<3).

Optionally, an oxidation grinding solution is used in the first grinding.

Optionally, the oxidation grinding solution is a potassium hydroxide solution or an ammonium hydroxide solution.

Optionally, after the second grinding of the residual layer by using the alkaline solution is performed, the method further includes cleaning a grinding pad by using deionized water; and cleaning the substrate or the wafer by using deionized water.

Compared with the prior art, the method according to embodiments of the present invention has the following advantages and benefits. The organic residues remaining on the surface of the dielectric layer are removed by the alkaline solution between the first grinding process and the cleaning process of the wafer, wherein the removing process is performed by a grinding method. Therefore the alkaline solution is sufficiently in contact with the surface of the dielectric layer. Compared with the conventional technique of cleaning the organic residues by the cleaning device in subsequent processes, embodiments of the present invention can remove the organic residues that remain on the surface of the dielectric layer more effectively and more thoroughly.

In an embodiment, the alkaline solution includes compositions of grinding particles, a cleaning agent, a chelating agent, an anti-corrosion compounds, and a surfactant. During the process of the second grinding, the compositions interact with each other to perform the thorough removal of the organic residues.

In another embodiment, while the surface of the dielectric layer is cleaned by the alkaline solution, the pressure on the wafer of the grinding head is set to be lower than the pressure of the grinding head in the first grinding, this setup thus prevents the abrasion of the surface of the wafer while grinding the particles and residues remaining thereon.

### BRIEF DESCRIPTION OF THE DRAWINGS

FIG. 1 is a flow chart of a CMP method according to an embodiment of the present invention;

FIGS. 2-5 are schematic cross-sectional views of intermediate structures of a dual damascene structure, illustrating a CMP method according to an embodiment of the present invention; and

FIG. 6(a) is a schematic diagram illustrating a result of the removal of organic residues according to a conventional method, and FIG. 6(b) is a schematic diagram illustrating a result of the removal of the organic residues remaining on a wafer surface according to an embodiment of the present invention.

### DETAILED DESCRIPTION OF THE INVENTION

A conventional CMP process uses a surfactant to remove organic residues remaining on a surface of a substrate or wafer. However, a large amount of residues is remaining on the surface of the substrate or wafer after cleaning the surface using a surfactant. As known to one of ordinary skill in the art, a surfactant is a type of stable bipolar micelle with both hydrophilic and hydrophobic properties, which may be arranged according to certain orientation on a solution surface and significantly reduce a surface tension thereof. Specifically, the organic residues are made of hydrophobic materials, such as copper inhibitors, BTA, and the like, most of which are water-insoluble. Therefore, when the surfactant contacts with the organic residues, because of a presence of the hydrophobic micelle, a repulsive force is much larger than an attraction force between the surfactant and the water molecules. Therefore, the surfactant molecules assemble on surfaces of the organic residues according to Van der Waals' forces of themselves, which forms a status that the hydrophilic micelle orientates outward and the hydrophobic micelle orientates inward, so that the organic residues are dispersed stably in the water, whereby the organic residues are removed from the wafer surface. However, it is found in practice that, by using this conventional cleaning process, it is difficult to completely remove the organic residues remaining on the wafer (used alternatively as substrate hereinafter) surface. A substantial large quantity of the organic residues is still adhering to the surface of the wafer (substrate) after the cleaning process.

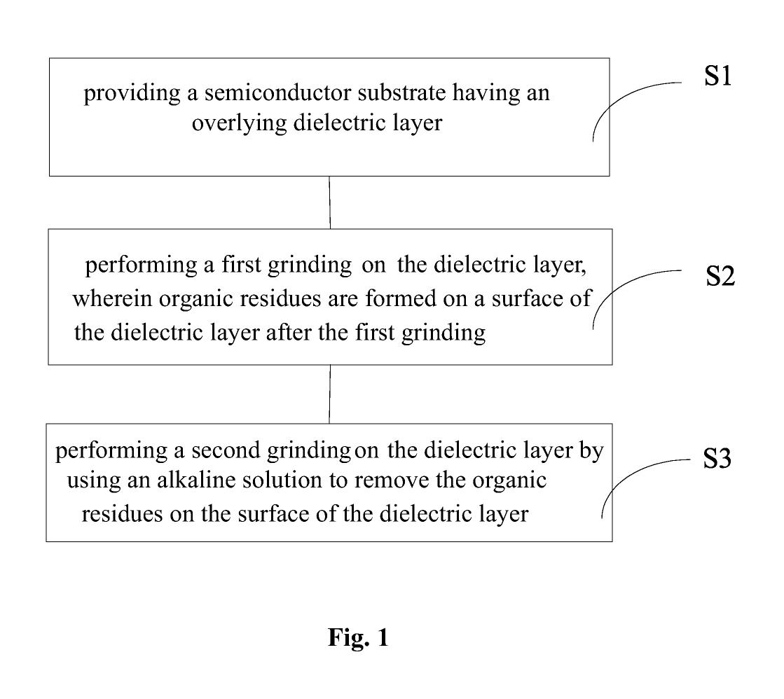

Embodiments of the present invention provide a method that can remove organic residues more effectively and thoroughly. FIG. 1 is a flow chart of a CMP method according to an embodiment of the present invention. At step S1, a semiconductor substrate having an overlying a dielectric layer is provided. Then, at step S2, a first grinding is performed on the dielectric layer, whereby the first grinding produces organic residues on a surface of the dielectric layer, and, at step S3, a second grinding is performed on the dielectric layer by using an alkaline solution to remove the organic residues on the surface of the dielectric layer.

In an embodiment, the grinding solution used in the first grinding is an oxidation grinding solution, such as a potassium hydroxide solution or an ammonium hydroxide solution. The oxidation grinding solution may include water, chemical aids, oxidation grinding particles, and the like. During the grinding, various organic compounds are produced by the chemical aids, which may adhere to a wafer surface to form organic residues.

In an embodiment, the alkaline solution may include grinding particles, a cleaning agent, a chelating agent, anti-corrosion compounds, and a surfactant, wherein a weight percentage of the grinding particles in the alkaline solution is from about 1% to about 15%, a weight percentage of the cleaning agent in the alkaline solution is from about 0.1% to about 5%, a weight percentage of the chelating agent in the alkaline solution is from about 0.01% to about 2%, a weight percentage of the anti-corrosion compounds in the alkaline solution is from about 0.01% to about 2%, and a weight percentage of the surfactant in the alkaline solution is from about 0.01% to about 1%.

In an embodiment, the grinding particles may be colloidal silica, silicon carbide, silicon nitride, aluminum oxide or cerium dioxide, and the grinding particles may have diameters within a range from about 35 nm to about 90 nm. The cleaning agent may include ammonium hydroxide or tetra alkyl ammonium hydroxide. In an embodiment, the chelating agent may include ammonium citrate or ammonium oxalate. In an embodiment, the anti-corrosion compounds may include acetamidophenol or methoxyphenol. In an embodiment, the surfactant may include polyoxyethylene or polypropylene. In an embodiment, the alkaline solution has a pH value within a range from about 8 to about 10. In addition, the surfactant may also remove the organic residues remaining on the surface of the wafer.

In conclusion, the method according to an embodiment of the present invention completes the first grinding process after performing steps S1 and S2. The method then executes step S3 to remove the organic residues remaining on the surface of the wafer by using an alkaline solution after the completion of the first grinding process. The method further cleans the wafer using a cleaning device in subsequent processes. In an embodiment, the cleaning device is a deionized water cleaning device. Compared with the prior art, the method according to an embodiment of the present invention executes the additional step S3 to remove organic residues remaining on the surface of the wafer. Step 3 is added after the first grinding process and before the cleaning process according to an embodiment of the present invention. It has been found that this additional step effectively removes the organic residues remaining on the surface of the wafer.

In an embodiment, the method further includes a cleaning process for cleaning a grinding pad and the wafer after the removal of the organic residues. In a specific embodiment, the cleaning process is performed by the deionized water device to remove various particles adhering to the wafer during the grinding process.

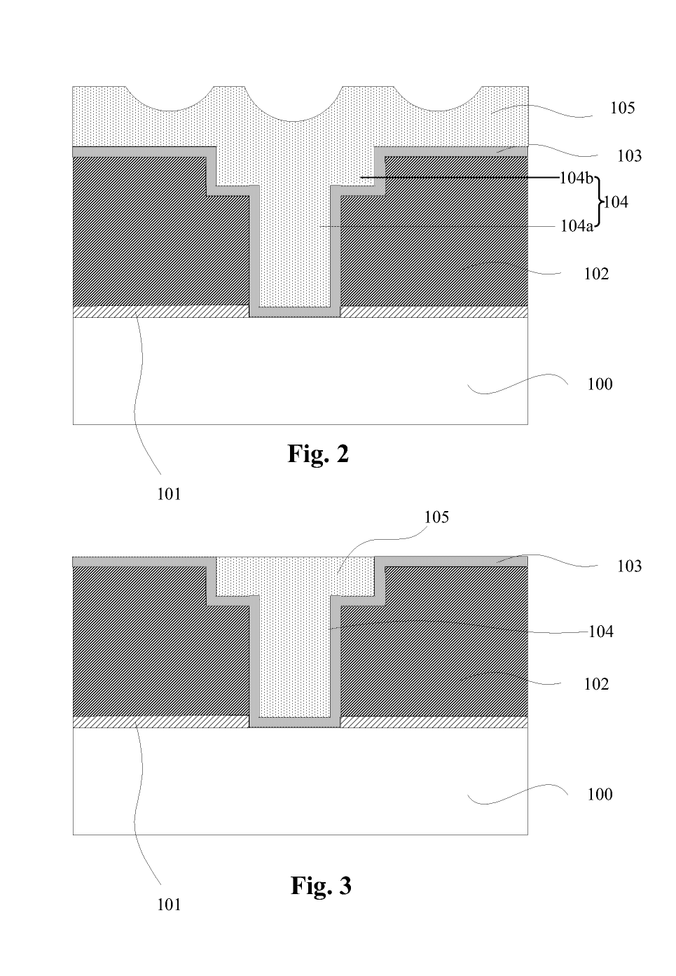

An embodiment of the present invention is described in detail together with the accompanying drawings below. Referring to FIGS. 2 to 4, a CMP process is performed when forming the dual damascene structure.

Referring to FIG. 2, a semiconductor substrate 100 having a metal wiring layer (not shown in FIG. 2) contained therein is provided. A covering layer (e.g., a metal barrier layer) 101 overlaying the metal wiring layer is formed on the semiconductor substrate 100. A dielectric layer 102 is formed on the covering layer 101 by using a Chemical Vapor Deposition (CVD) process. In an embodiment, dielectric layer 102 is made of SiO₂ or low K materials (K is a dielectric constant and less than 3), and the like.

In an embodiment, the covering layer 101 may prevent the metal wiring layer in the semiconductor substrate 100 from diffusing into the dielectric layer 102 and also prevent the metal wiring layer from being etched during an etching process.

Referring still to FIG. 2, a dual damascene structure 104 is formed by etching the dielectric layer 102. The process for forming the dual damascene structure 104 includes depositing a first photoresist layer (not shown in the figures) on the dielectric layer 102 and defining a through-hole pattern on the first photoresist through a photolithographic process. Using the first photoresist layer as a mask, a through-hole 104a is formed by etching the dielectric layer 102 through the through-hole pattern until the metal wiring layer is exposed; a second photoresist layer (not shown in the figures) is formed on the dielectric layer 102 and in the through-hole 104a after the first photoresist layer is removed, a groove pattern is defined on the second photoresist layer through a development process; and making the second photoresist layer as a mask, a groove 104b connecting with the through-hole 104a is formed by etching the dielectric layer 102 through the groove pattern. The dual damascene structure 104 includes the through-hole 104a and the groove 104b.

In an alternative embodiment, the groove may be first formed in the dielectric layer and then the through-hole is formed through the groove and exposes the metal wiring layer.

Referring still to FIG. 2, a stop layer 103 is formed on the dielectric layer 102, on sidewalls and a bottom of the dual damascene structure 104. In an embodiment, the stop layer 103 is made of one of tantalum, tantalum oxide, or tantalum silicon nitrogen. Then, a metal layer 105 is deposited on the stop layer 103 that is used to prevent the metal layer 105 and the dielectric 102 from diffusing into each other and thus affecting the performance of the final product. In an embodiment, the metal layer 105 is made of Cu which is filled into the dual damascene structure 104 completely by an Electric Vapor Deposition (EVD) process.

Referring to FIG. 3, a dual damascene conducting structure is formed by performing a CMP process to the metal layer 105 until the stop layer 103 is exposed, wherein an Al₂O₃ grinding solution may be used. For forming a metal layer 105 with desired flatness and uniformity, a rough grinding and a smooth grinding can be performed on the metal layer 105 in an embodiment.

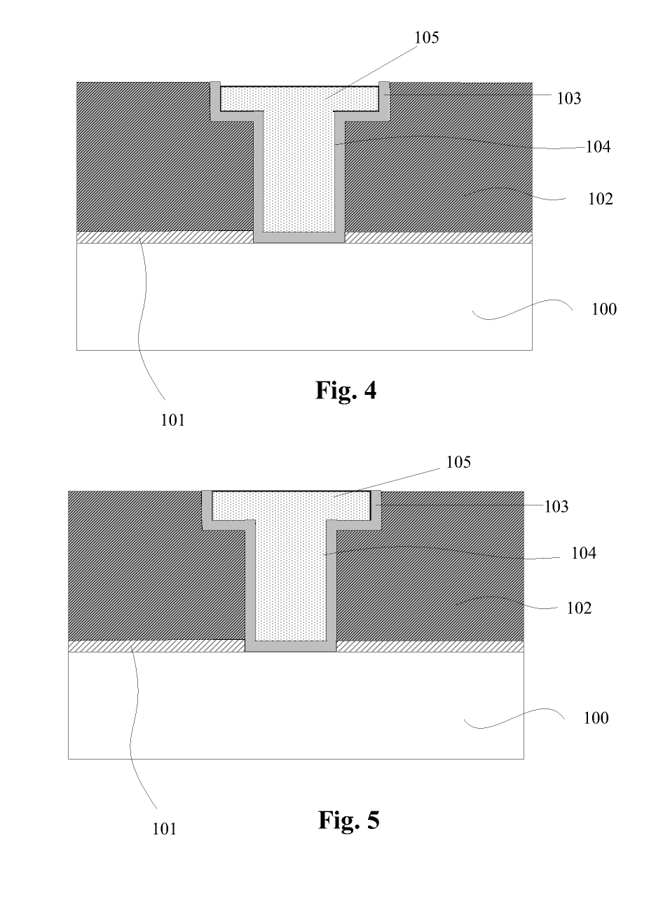

As shown in FIG. 4, the stop layer 103 is grinded by using the CMP method until the dielectric layer 102 is exposed, wherein the grinding solution used in the CMP process is selected according to the characteristics of materials of the stop layer 103e. Because the metal layer 105 and the stop layer 103 are made of different materials, grinding rates of the grinding solution to the metal layer 105 and the stop layer 103 are different, so that the metal layer 105 is normally lower than the dielectric layer 102 after the stop layer 103 is grinded until the dielectric layer 102 is exposed. Therefore, the dielectric layer 102 may be further grinded to be substantially flush (coplanar) with the metal layer 105.

As shown in FIG. 5, a first grinding is performed on the dielectric layer 102. In an embodiment, an oxidation solution may be used to perform the first grinding on the dielectric layer. In the first grinding, the dielectric layer 102 is a low-K dielectric layer, wherein the dielectric constant K is less than 3. In an embodiment, the oxidation solution may be a potassium hydroxide solution or an ammonium hydroxide solution. The first grinding is used to planarize the dielectric layer 102 in order to make the dielectric layer 102 to be substantially flush (coplanar) with the metal layer 105. Water in the oxidation grinding solution reacts with silicon oxide in the dielectric layer 102 to produce oxyhydrogen bonds, which is termed surface hydration. Hardness and mechanical strength of the silicon oxide are reduced by the hydration on the surface thereof, whereby silicon oxide layer with soft surface containing water is produced. Then, the softened silicon oxide layer is removed by grinding particles in the grinding solution in order to planarize the dielectric layer 102. Further, after the first grinding is performed, organic residues are formed on the surface of the dielectric layer 102, which are mainly from the oxidation grinding solution used.

Therefore, a second grinding is performed on the dielectric layer 102 by using an alkaline solution to remove the organic residues remaining on the surface thereof. Specifically, the alkaline solution includes grinding particles, a cleaning agent, a chelating agent, anti-corrosion compounds and a surfactant, wherein a weight percentage of the grinding particles in the alkaline solution is from about 1% to about 15%, a weight percentage of the cleaning agent in the alkaline solution is from about 0.1% to about 5%, a weight percentage of the chelating agent in the alkaline solution is ranged from about 0.01% to about 2%, a weight percentage of the anti-corrosion compounds in the alkaline solution is from about 0.01% to about 2%, and a weight percentage of the surfactant in the alkaline solution is from about 0.01% to about 1%. The alkaline solution may further include solvent, like deionized water.

The grinding particles may be colloidal silica, having diameters within a range from about 35 nm to about 90 nm. In an embodiment, the grinding particles may be silicon carbide, silicon nitride, aluminum oxide, cerium dioxide, or the like. In an embodiment, the cleaning agent may include an ammonium hydroxide or tetra alkyl ammonium hydroxide, which is alkaline. A weight percentage of the cleaning agent in the alkaline agent may be used to adjust a pH value of the alkaline solution. In an embodiment, the alkaline solution has a pH value within a range from about 8 to about 10. In an embodiment, the chelating agent may include ammonium citrate or ammonium oxalate. The anti-corrosion compounds may include acetamidophenol or methoxyphenol. In an embodiment, the surfactant includes polyoxyethylene or polypropylene.

Further, when Cu is grinded by the CMP process, the alkaline solution may include H₂O₂ having a weight percentage ranging from about 0.3% to about 1%. H₂O₂ may be an accelerating agent for removing Cu.

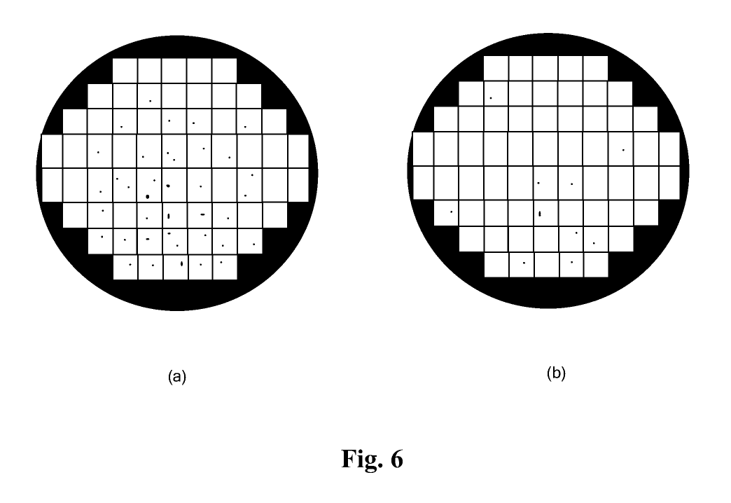

FIG. 6(a) is a schematic diagram illustrating a result of removing organic residues on a wafer surface using a conventional CMP method, and FIG. 6(b) is a schematic diagram illustrating a result of removing organic residues on a wafer surface according to an embodiment of the present invention. FIG. 6(a) shows that the result of removing the organic residues remaining on the wafer surface after cleaning the wafer in subsequent processes according to the conventional art. FIG. 6(b) shows the result of removing the organic residues remaining on the wafer surface by using the alkaline solution before using the cleaning device to cleaning the wafer surface according to an embodiment of the present invention. It can be seen clearly that the alkaline solution removes the organic residues remaining on the surface of the wafer more effectively. And the remained organic residues after the alkaline solution can further be removed by using the deionized water device in subsequent processes. Compared with the conventional art, the method according to the embodiments in the present invention can remove the organic residues remaining on the wafer surface more effectively.

Furthermore, during the process of removing the organic residues on the surface of the dielectric layer 102 by using the alkaline solution, a pressure of a grinding head on the wafer is set to be lower than the pressure in the first grinding process in order to prevent the wafer surface form being abraded by the grinding particles left over thereon. In an embodiment, during the first grinding process, the pressure of the grinding head is from about 0.85 psi to about 1.8 psi. While using the alkaline solution to remove the organic residues left over on the surface of the dielectric layer, the pressure of the grinding head is set to be from about 0.5 psi to about 0.7 psi.

In conclusion, in the method provided by embodiments of the present invention, the organic residues remaining on the surface of the dielectric layer are removed by using the alkaline solution after the first grinding process is performed to the wafer, and the cleaning device is then used to clean the wafer. Compared with conventional techniques, embodiments of the present invention provide a method that can removes organic residues more effectively and thoroughly. Moreover, if an alkaline solution is used to clean the surface of the dielectric layer, the pressure of the grinding head is set to be lower than the pressure of the grinding head in the first grinding process in order to effectively prevent the wafer surface form being abraded by the grinding particles left over thereon.

It should be noted that embodiments disclosed herein use the formation of a dual damascene structure as an example to illustrate the CMP method that can removes organic residues effectively from a substrate or wafer surface. The method and drawings shown are merely examples, which should not unduly limit the scope of the claims herein. One of ordinary skill in the art would recognize other variations, modifications, and alternatives. For example, the disclosed method can be used in a CMP process of other structures in the field of semiconductor technology, such as conductive plug structures, shallow slot isolation structures, metal wiring processes, and the like, which may not be specifically illustrated herein. The CMP method provided by embodiments herein may be used in other types of planarization processes including grinding of dielectric layers.

Although the present invention has been disclosed above with reference to preferred embodiment thereof, it should be understood that the invention is presented by way of example only, and not limitation. Those skilled in the art can modify and vary the embodiment without departing from the spirit and scope of the present invention.

What is claimed is:

1. A chemical mechanical polishing (CMP) method, comprising:
providing a semiconductor substrate having an overlying dielectric layer;
performing a first grinding on the dielectric layer, the first grinding producing organic residues on a surface of the dielectric layer; and
performing a second grinding on the dielectric layer by using an alkaline solution to remove the organic residues on the surface of the dielectric layer.

2. The CMP method according to claim 1, wherein the alkaline solution comprises grinding particles, a cleaning agent, a chelating agent, anti-corrosion compounds, and a surfactant.

3. The CMP method according to claim 2, wherein a weight percentage of the grinding particles in the alkaline solution is from about 1% to about 15%, a weight percentage of the cleaning agent in the alkaline solution is from about 0.1% to about 5%, a weight percentage of the chelating agent in the alkaline solution is from about 0.01% to about 2%, a weight percentage of the anti-corrosion compounds in the alkaline solution is from about 0.01% to about 2%, and a weight percentage of the surfactant in the alkaline solution is from about 0.01% to about 1%.

4. The CMP method according to claim 2, wherein the grinding particles comprise colloidal silica, silicon carbide, silicon nitride, aluminum oxide or cerium dioxide.

5. The CMP method according to claim 2, wherein the grinding particles have diameters ranging from about 35 nm to about 90 nm.

6. The CMP method according to claim 2, wherein the cleaning agent comprises ammonium hydroxide or tetra alkyl ammonium hydroxide.

7. The CMP method according to claim 2, wherein the chelating agent comprises ammonium citrate or ammonium oxalate.

8. The CMP method according to claim 2, wherein the anti-corrosion compounds comprise acetamidophenol or methoxyphenol.

9. The CMP method according to claim 2, wherein the surfactant comprises polyoxyethylene and polypropylene.

10. The CMP method according to claim 2, wherein the alkaline solution has a pH value ranging from about 8 to about 10.

11. The CMP method according to claim 1, wherein a pressure of a grinding head is ranged from about 0.85 psi to about 1.8 psi during the first grinding.

12. The CMP method according to claim 1, wherein the pressure of the grinding head is in the range from about 0.5 psi to about 0.7 psi during the second grinding.

13. The CMP method according to claim 1, wherein the dielectric layer is a low-K dielectric layer.

14. The CMP method according to claim 13, wherein the low-K dielectric layer comprises a dielectric constant K less than 3.

15. The CMP method according to claim 1, wherein the first grinding comprises an oxidation grinding solution.

16. The CMP method according to claim 15, wherein the oxidation grinding solution comprises a potassium hydroxide solution or an ammonium hydroxide solution.

17. The CMP method according to claim 1 further comprising:
after the second grinding is performed on the dielectric layer by the alkaline solution, cleaning a grinding pad by using deionized water; and
cleaning a wafer by using deionized water.
